(19) United States
(12) Patent Application Publication
(10) Pub. No.: US 2025/0293201 A1
(43) Pub. Date: Sep. 18, 2025

(54) POWER CHIP PACKAGE STRUCTURE AND MANUFACTURING METHOD THEREOF

(71) Applicant: TONG HSING ELECTRONIC INDUSTRIES, LTD., Taipei City (TW)

(72) Inventors: Yu-Te Hsieh, Taipei City (TW); Wei-Chung Chao, Taipei City (TW); Yan-Wei Chen, Taipei City (TW); Zzu-Chi Chiu, Taipei City (TW)

(73) Assignee: TONG HSING ELECTRONIC INDUSTRIES, LTD., Taipei City (TW)

(21) Appl. No.: 18/666,844

(22) Filed: May 17, 2024

(30) Foreign Application Priority Data
Mar. 14, 2024 (TW) 113109355

(51) Int. Cl. H01L 23/00; H01L 23/373

(52) U.S. Cl. CPC H01L 24/83; H01L 23/3735; H01L 24/29; H01L 24/32; H01L 2224/27011; H01L 2224/29139; H01L 2224/32225; H01L 2224/83385; H01L 2224/8349; H01L 2224/8384

(57) ABSTRACT

A power chip package structure and a manufacturing method thereof are disclosed. The power chip package structure includes a carrier, a self-correction layer, a conductive paste, and a power chip. The carrier includes a ceramic board and an inner metal layer that is formed on the ceramic board and that has a connection pad. The self-correction layer is formed on the inner metal layer, and the self-correction layer and the connection pad jointly define a slot. The self-correction layer includes a glue body and a plurality of elastic spacers covered by the glue body. The conductive paste is filled into the slot. The power chip includes a chip body disposed on the self-correction layer and a bonding pad that is formed on the chip body. The bonding pad is connected to the conductive paste, such that the power chip is electrically coupled to the carrier.

### BACKGROUND OF THE INVENTION

### 1. Field of the Invention

The present invention relates to a package structure, and in particular to a power chip package structure and a manufacturing method thereof.

### 2. Description of the Prior Art

When the existing power chip package structure adopts a wire-less architecture, the power chip in the existing power chip package structure is prone to tilt, thereby causing a problem of poor reliability. Therefore, the inventor believed that the above-mentioned defects could be improved, so he devoted himself to research and applied scientific principles, and finally proposed an invention that is reasonably designed and effectively improves the above-mentioned defects.

### SUMMARY OF THE INVENTION

Embodiments of the present invention provide a power chip package structure and a manufacturing method thereof, which can effectively improve the defects that may occur in the existing power chip package structure.

An embodiment of the present invention discloses a method for manufacturing a power chip package structure including a pre-step: providing a first carrier including a first ceramic board and a first inner metal layer formed on an inner plate surface of the first ceramic board, wherein the first inner metal layer has at least one first connection pad; a forming step: forming a first self-correction layer on the first inner metal layer, which has at least one first slot exposing the at least one first connection pad, wherein the first self-correction layer includes a first glue body in a partially cured state (B-stage), and a plurality of first elastic spacers disposed in the first glue body; a filling step: filling at least one first conductive paste into the at least one first slot; a chip placement step: using a jig to place a power chip on the first self-correction layer and the at least one first conductive paste, so that at least one first bonding pad of the power chip is connected to the at least one first conductive paste, and at least one of the plurality of first elastic spacers is compressed and deformed by pressure from the power chip; a self-correction step: removing the jig to restore the compressed and deformed at least one of the plurality of first elastic spacers to its original shape so as to push and move the power chip to a preset position; and a curing step: sintering the at least one first conductive paste and curing the first glue body so that the power chip is fixed to the at least one first conductive paste and the first self-correction layer.

Another embodiment of the present invention discloses a power chip package structure including a first carrier including a first ceramic board and a first inner metal layer formed on an inner plate surface of the first ceramic board, wherein the first inner metal layer has at least one first connection pad; a first self-correction layer formed on the first inner metal layer, and the first self-correction layer and the at least one first connection pad together form at least one first slot; wherein the first self-correction layer includes a first glue body and a plurality of first elastic spacers disposed in the first glue body; at least one first conductive paste filled into the at least one first slot; and a power chip including: a chip body disposed on the first self-correction layer; and at least one first bonding pad formed on a first surface of the chip body, wherein the at least one first bonding pad is connected to the at least one first conductive paste, so that the power chip is electrically coupled to the first carrier.

Still another embodiment of the present invention discloses a power chip package structure including: a first carrier including a first ceramic board and a first inner metal layer formed on an inner plate surface of the first ceramic board, wherein the first inner metal layer has at least one first connection pad; a first self-correction layer including a plurality of correction blocks formed on the first inner metal layer, wherein the plurality of the correction blocks are spaced apart from each other and disposed around the at least one first connection pad, wherein each of the plurality of correction blocks includes a first glue body and a plurality of first elastic spacers disposed in the first glue body; at least one first conductive paste formed on the at least one first connection pad; and a power chip including: a chip body disposed on the first self-correction layer, and multiple corners of the chip body are respectively disposed on the plurality of the correction blocks; and at least one first bonding pad formed on a first surface of the chip body, wherein the at least one first bonding pad is connected to the at least one first conductive paste such that the power chip is electrically coupled to the first carrier.

To sum up, in the power chip package structure and the manufacturing method thereof disclosed in the embodiments of the present invention, the first self-correction layer is disposed between the first carrier and the power chip, so that during the production process of the power chip package structure, the power chip can be maintained in a preset position by the plurality of first elastic spacers, thereby preventing the power chip from being tilted relative to the first carrier, so as to achieve better reliability performance. In addition, the size of the first self-correction layer can be adjusted according to actual needs.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a three-dimensional schematic diagram of a power chip package structure according to Embodiment I of the present invention.

FIG. 2 is a schematic cross-sectional view taken along line II-II in FIG. 1.

FIG. 3 is a schematic cross-sectional view taken along line III-III in FIG. 1 (the molding compound is omitted).

FIG. 4 is a schematic cross-sectional view taken along line IV-IV in FIG. 1 (the molding compound is omitted).

FIG. 5 is a schematic flowchart of a method for manufacturing a power chip package structure according to Embodiment I of the present invention.

FIG. 6 is a schematic diagram of the pre-step and the forming step of FIG. 5.

FIG. 7 is a schematic diagram of the filling step and the chip placement step of FIG. 5.

FIG. 8 is a schematic diagram of the self-correction step of FIG. 5.

FIG. 9 is a schematic cross-sectional view of a power chip package structure according to Embodiment II of the present invention.

FIG. 10 is a schematic cross-sectional view of a power chip package structure according to Embodiment III of the present invention (the molding compound is omitted).

### DETAILED DESCRIPTION

The following is a specific example to illustrate the implementation of the “power chip package structure and manufacturing method thereof” disclosed in the present invention. Those skilled in the art can understand the advantages and effects of the present invention from the content disclosed in this specification. The present invention can be implemented or applied through other different specific embodiments, and various details in this specification can also be modified and changed based on different viewpoints and applications without departing from the concept of the present invention. In addition, the drawings of the present invention are only simple schematic illustrations and are not depictions based on actual dimensions, as is stated in advance. The following embodiments will further describe the relevant technical content of the present invention in detail, but the disclosed content is not intended to limit the scope of the present invention.

It should be understood that although terms such as “first”, “second” and “third” may be used herein to describe various elements or signals, these elements or signals should not be limited by these terms. These terms are primarily used to distinguish one component from another component or one signal from another signal. In addition, the term “or” used in this article shall include any one or combination of more of the associated listed items depending on the actual situation.

### Embodiment I

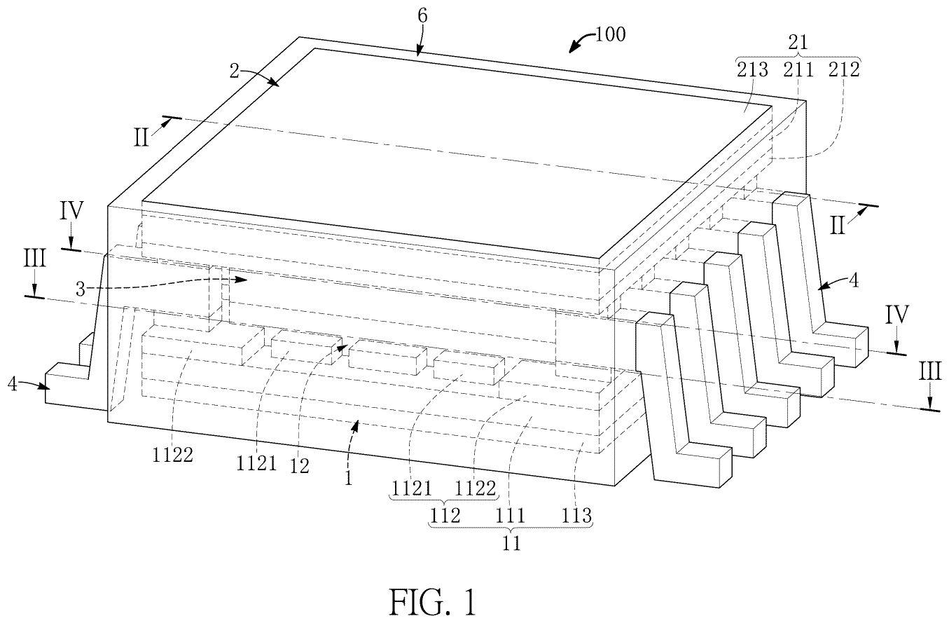

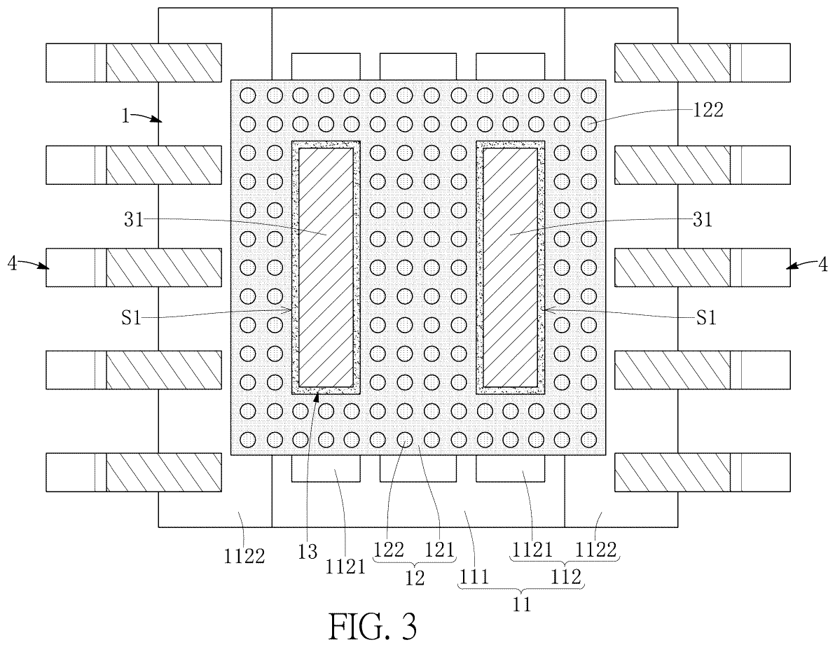

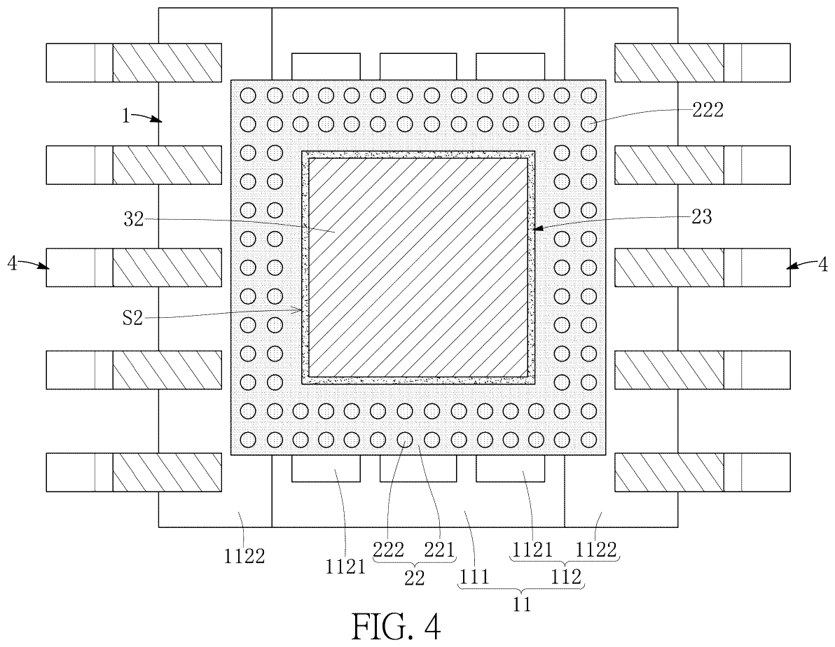

Please refer to FIG. 1 to FIG. 8, which illustrate Embodiment I of the present invention. This embodiment discloses a power chip package structure 100 and its manufacturing method S100. To facilitate the description of this embodiment, the structure of each component of the power chip package structure 100 and its connection relationship will be introduced first, and then the main implementation steps of the power chip package structure manufacturing method S100.

As shown in FIG. 1 to FIG. 4, the power chip package structure 100 adopts a wireless architecture in this embodiment, and the power chip package structure 100 includes a first module 1, a second module 2 spaced apart from the first module 1, a power chip 3 clamped and fixed between the first module 1 and the second module 2, and multiple pins 4 spaced apart from each other and disposed around the power chip 3.

The power chip 3 comprises a chip body 33, two first bonding pads 31 formed on one side of the chip body 33, and a second bonding pad 32 formed on the other side of the chip body 33. In this embodiment, the chip body 33 has a first surface 331 and a second surface 332 opposite to the first surface 331. The two first bonding pads 31 are formed on the first surface 331 and are spaced apart from each other. The two first bonding pads 31 may be a source pad and a gate pad, respectively. The second bonding pad 32 is formed on the second surface 332 and may be a drain pad, but not limited thereto.

It is noteworthy that the type of the power chip 3 can be adjusted and changed according to actual needs. For example, the power chip 3 can be an insulated gate bipolar transistor (IGBT), a power MOSFET, a bipolar junction transistor (BJT), a silicon carbide (SiC) power device, a gallium nitride (GaN) power device, a high electron mobility transistor (HEMT), or a fast recovery diode (FRD). Further, the number of the power chip 3 can also be adjusted according to actual needs.

The first module 1 includes a first carrier 11, a first self-correction layer 12 formed on the first carrier 11, and two first conductive pastes 13. The first carrier 11 includes a first ceramic board 111, a first inner metal layer 112 formed on the inner plate surface of the first ceramic board 111, and a first outer metal layer 113 formed on the outer plate surface of the first ceramic board 111.

In this embodiment, the first carrier 11 is a direct bonded copper (DBC) ceramic substrate, and the first inner metal layer 112 and the first outer metal layer 113 are sintered and fixed on the inner plate surface and the outer plate surface of the first ceramic board 111, respectively, but not limited thereto. For example, in some embodiments, the first inner metal layer 112 and the first outer metal layer 113 may be formed by direct plated copper (DPC) technology or formed by using active metal brazing (AMB) technology on the inner plate surface and the outer plate surface of the first carrier 11, respectively.

Furthermore, the first inner metal layer 112 comprises two spaced-apart first connection pads 1121 and a first metal pad 1122 located outside the two first connection pads 1121. The first inner metal layer 112 comprises a plurality of first gaps G1 surrounding the two first connection pads 1121. From another perspective, except for the two first connection pads 1121, the layout of other parts of the first inner metal layer 112 can be adjusted and changed according to actual needs.

The first self-correction layer 12 is formed on the first inner metal layer 112. The first self-correction layer 12 and each of the first connection pads 1121 together form a first slot S1. The first self-correction layer 12 includes a first glue body 121 and a plurality of first elastic spacers 122 disposed in the first glue body 121.

More specifically, the first glue body 121 is preferably a low-stress resin, and the first glue body 121 fills each of the first gaps G1. Furthermore, each of the first elastic spacers 122 may be an elastic ball made of polymer material. These elastic balls have an average diameter. A difference between the diameter of each elastic ball and the average diameter is preferably not greater than 5 micrometers (μm).

The two first conductive pastes 13 are respectively filled into the two first slots S1. Each of the first conductive pastes 13 may be a sintering silver paste in this embodiment, but not limited thereto.

The power chip 3 is disposed on the first self-correction layer 12, and the first surface 331 of the chip body 33 is bonded to the first glue body 121. The two first bonding pads 31 are connected to the two first conductive pastes 13 respectively, so that the power chip 3 is electrically coupled to the first carrier 11. Preferably, the first surface 331 of the power chip 3 is completely covered by the first self-correction layer 12 and the two first conductive pastes 13. The top edges of the plurality of elastic balls of the first self-correction layer 12 are substantially aligned with the top surface of the first glue body 121 and are in contact with the first surface 331 of the power chip 3.

The number of the first slots S1, the number of the first connection pads 1121, and the number of the first conductive pastes 13 are two for each in this embodiment, which correspond to the two first bonding pads 31 of the power chip 3. However, the invention is not limited thereto. It is to be understood that the number of the first connection pads 1121, the number of the first slots S1, the number of the first bonding pads 31, and the number of the first conductive pastes 13 can also be adjusted to at least one according to actual needs.

As disclosed above, the power chip package structure 100 in this embodiment uses the first self-correction layer 12 interposed between the first carrier 11 and the power chip 3 so that during the production process of the power chip package structure 100, the power chip 3 can be continuously supported by the plurality of first elastic spacers 122 and maintained in a preset position, thereby preventing the power chip 3 from being tilted relative to the first carrier 11 and maintaining better reliability.

The second module 2 includes a second carrier 21, a second self-correction layer 22 and a second conductive paste 23 formed on the second carrier 21. The second carrier 21 includes a second ceramic board 211, a second inner metal layer 212 formed on the inner plate surface of the second ceramic board 211, and a second outer metal layer 213 formed on the outer plate surface of the second ceramic board 211.

In this embodiment, the second carrier 21 is a direct bonded copper (DBC) ceramic substrate, and the second inner metal layer 212 and the second outer metal layer 213 are sintered and fixed on the inner plate surface and the outer plate surface of the second ceramic boards 211, respectively, but not limited thereto. For example, in some embodiments, the second inner metal layer 212 and the second outer metal layer 213 may be formed by direct plated copper (DPC) technology or formed by using active metal brazing (AMB) technology on the inner plate surface and the outer plate surface of the second carrier 21, respectively.

Furthermore, the second inner metal layer 212 comprises a second connection pad 2121 and a second metal pad 2122 located outside two of the second connection pads 2121. The second inner metal layer 212 comprises a second gap G2 formed around the second connection pad 2121. From another perspective, except for the second connection pad 2121, the layout of other parts of the second inner metal layer 212 can be adjusted and changed according to actual needs.

The second self-correction layer 22 is formed on the second inner metal layer 212. The second self-correction layer 22 and the second connection pad 2121 together form a second slot S2. The second self-correction layer 22 includes a second glue body 221 and a plurality of second elastic spacers 222 disposed in the second glue body 221.

More specifically, the second glue body 221 is preferably a low-stress resin, and the second glue body 221 fills the second gap G2. Furthermore, each of the second elastic spacers 222 may be an elastic ball made of polymer material. These elastic balls have an average diameter. A difference between the diameter of each elastic ball and the average diameter is preferably not greater than 5 micrometers (μm).

The second conductive paste 23 is filled into the second slot S2. The second conductive paste 23 may be a sintering silver paste in this embodiment, but not limited thereto.

The power chip 3 is disposed on the second self-correction layer 22, and the second surface 332 of the chip body 33 is bonded to the second glue body 221. The second bonding pad 32 is connected to the second conductive paste 23, so that the power chip 3 is electrically coupled to the second carrier 21. Preferably, the second surface 332 of the power chip 3 is completely covered by the second self-correction layer 22 and the second conductive paste 23. The top edges of the plurality of elastic balls of the second self-correction layer 22 are substantially aligned with the top surface of the second glue body 221 and are in contact with the second surface 332 of the power chip 3.

The number of the second slot S2, the number of the second connection pad 2121, and the number of the second conductive paste 23 are one for each in this embodiment, which correspond to the second bonding pads 31 of the power chip 3. However, the invention is not limited thereto. It is to be understood that the number of the first connection pads 1121, the number of the first slots S1, the number of the first bonding pads 31, and the number of the first conductive paste 13 can also be adjusted to more than one according to actual needs.

As disclosed above, the power chip package structure 100 in this embodiment uses the second self-correction layer 22 interposed between the second carrier 21 and the power chip 3 so that during the production process of the power chip package structure 100, the power chip 3 can be continuously supported by the plurality of first elastic spacers 222 and maintained in a preset position, thereby preventing the power chip 3 from being tilted relative to the second carrier 21 so as to achieve better reliability performance.

Further, the multiple pins 4 are clamped and fixed between the first carrier 11 and the second carrier 21. Each of the pins 4 can be connected and fixed to the first carrier 11 and the second carrier 21 through a conductive material (e.g., a conductive paste), so that each of the pins 4 is electrically coupled to the first carrier 11 and the second carrier 21. The power chip package structure 100 in this embodiment further includes a molding compound 6 so that the first module 1, the second module 2, and the power chip 3 are embedded in the molded compound 6. Each of the pin 4 protrudes from the molded compound 6. The first outer metal layer 113 and the second outer metal layer 213 are exposed from the molded compound 6, thereby improving heat dissipation performance.

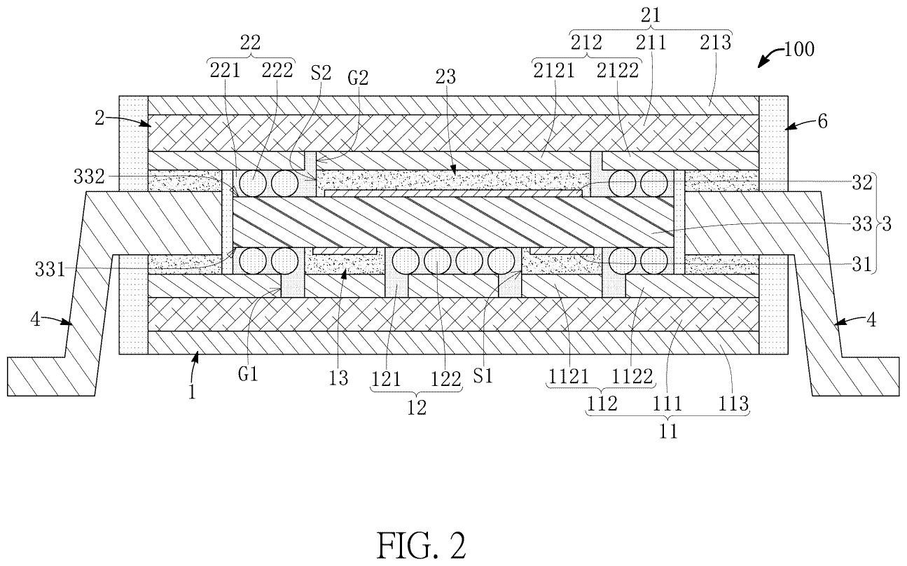

As shown in FIG. 2 and FIGS. 5-8, the above is a structural description of the power chip package structure 100 in this embodiment. Subsequently, the manufacturing method S100 of the power chip package structure will be briefly introduced. The technical content may be referred to the above description of the power chip package structure 100. However, it is understood that the power chip package structure 100 may be manufactured by other methods, and not limited to the manufacturing method S100.

Further, in order to facilitate understanding of this embodiment, only the manufacturing process between the first module 1 and the power chip 3 will be described below. The manufacturing method S100 of the power chip package structure in this embodiment sequentially includes (or implements) a pre-step S110, a forming step S120, a filling step S130, a chip placement step S140, and a self-correction step S150, and a curing (sintering) step S160.

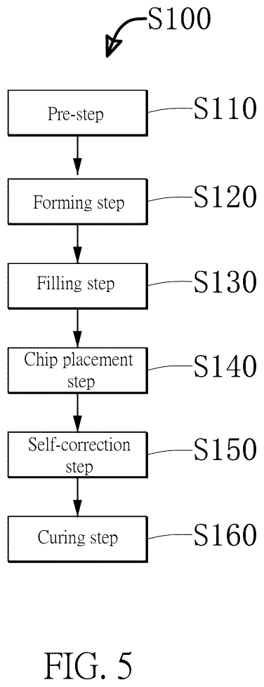

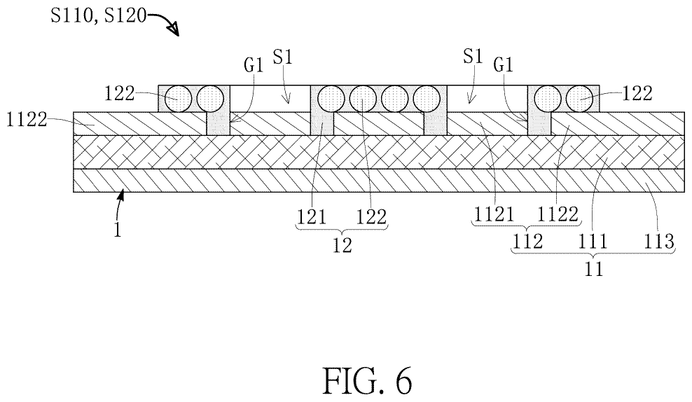

The pre-step S110: as shown in FIG. 5 and FIG. 6, a first carrier 11 is provided, including a first ceramic board 111 and a first inner metal layer 112 formed on the inner plate surface of the first ceramic board 111. The first inner metal layer 112 has at least one first connection pad 1121, and the first inner metal layer 112 is formed with at least one first gap G1 around the at least one first connection pads 1121.

The forming step S120: as shown in FIG. 5 and FIG. 6, a first self-correction layer 12 is formed on the first inner metal layer 112, which has at least one first slot SI that exposes the at least one first connection pads 1121. The first self-correction layer 12 includes a B-stage first glue body 121 and a plurality of first elastic spacers 122 disposed in the first glue body 121. Furthermore, the first glue body 121 fills the at least one first gaps G1. Each of the first elastic spacers 122 may be an elastic ball made of polymer material.

It should be noted that the first self-correction layer 12 can be heated to 120 degrees Celsius in the forming step S120 to perform pre-drying to volatilize some solvents in the first glue body 121, but not limited thereto.

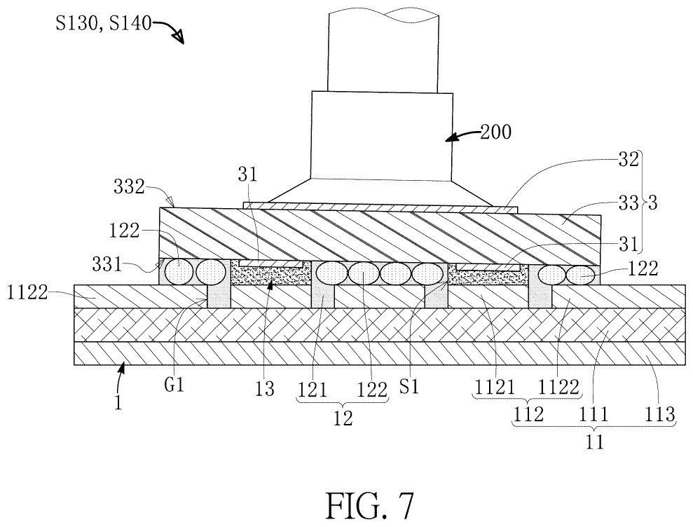

The filling step S130: as shown in FIG. 5 and FIG. 7, at least one first conductive paste 13 is filled into the at least one first slot S1. The at least one first conductive paste 13 in this embodiment may be a silver paste. It should be noted that the first conductive paste 13 can be heated to 130 degrees Celsius in the filling step S130 to perform pre-drying, but not limited thereto.

The chip placement step S140: as shown in FIG. 5 and FIG. 7, a power chip 3 is placed onto the first self-correction layer 12 and the at least one first conductive paste 13 with a jig 200, so that the at least one first bonding pad 31 of the power chip 3 is connected to the at least one first conductive paste 13. At least one first elastic spacer 122 may be compressed and deformed by the power chip 3. It should be noted that the power chip 3 may be hot tacked with a force of 400 grams and under a temperature of 170 degrees Celsius for at least 3 seconds in the chip placement step S140 of this embodiment, but not limited thereto.

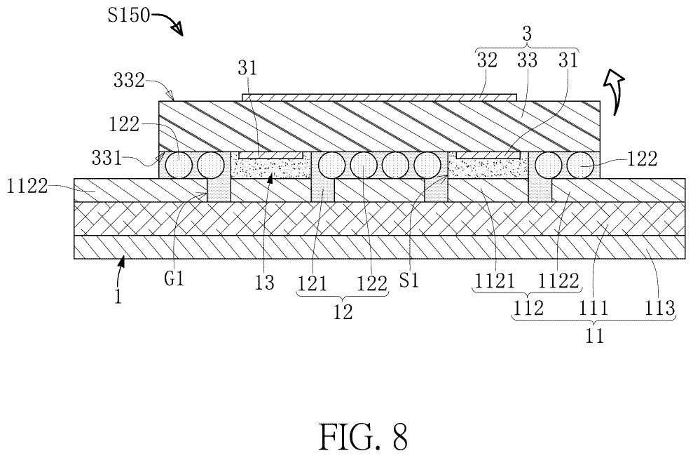

The self-correction step S150: as shown in FIG. 5 and FIG. 8, the jig 200 is removed, so that the at least one of the first elastic spacers 122 that is compressed and deformed returns to its original shape and pushes and moves the power chip 3 to a preset position. In the self-correction step S150, the first glue body 121 is heated in the chip placement step S140, so that its fluidity is higher than that of the first glue body 121 in the forming step S120, thereby facilitating the at least one first elastic body 122 that is compressed and deformed to return to its original shape within the first glue body 121.

The curing (sintering) step S160: As shown in FIG. 5 and FIG. 2, the first conductive paste 13 is sintered and the first glue body 121 is cured with a sintering profile, so that the power chip 3 is fixed on the first conductive paste 13 and the first self-correction layer 12. The top edges of the plurality of elastic balls are substantially aligned with the top surface of the first glue body 121 and are in contact with the power chip 3.

More specifically, in this embodiment, the sintering process of the first conductive paste 13 may be performed in an environment of 200˜300 degrees Celsius, using pressure-less sintering or pressure-assisted sintering at a pressure of 20˜40 MPa depending upon actual needs, but not limited thereto.

The number of the at least one first connection pad 1121, the number of the at least one first slot S1, the number of the at least one first bonding pad 31, and the number of the at least one first conductive paste 13 are two of each in this embodiment, but not limited thereto. Further, the assembly process between the second module 2 and the power chip 3 is similar to the above-mentioned steps: S110 to S160. After the second module 2 is installed on the power chip 3, it is further processed through a packaging step (not shown in the figure) so as to form the molding compound 6, and the details will not be described again here.

### Embodiment II

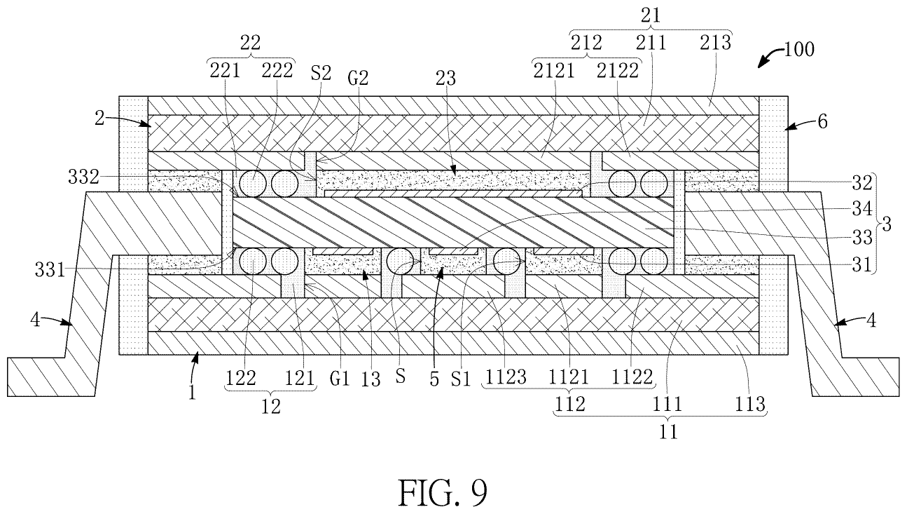

Please refer to FIG. 9, which shows Embodiment II of the present invention. Since this embodiment is similar to the above-mentioned Embodiment I, the common features between the two embodiments will not be described in detail. The differences between this embodiment and the above-mentioned Embodiment I are briefly summarized as follows.

In this embodiment, the first inner metal layer 112 has a thermal pad 1123 located between the two first connection pads 1121, and the first self-correction layer 12 and the thermal pad 1123 jointly form a receiving slot S. Furthermore, the power chip package structure 100 includes a thermal conductive paste 5 filled into the receiving slot S. The power chip 3 has a heat dissipation pad 34 formed on the first surface 331, and the heat dissipation pad 34 is located between the two first bonding pads 31 and connected to the thermal conductive paste 5. The thermal conductive paste 5 may be silver paste, but not limited thereto.

### Embodiment III

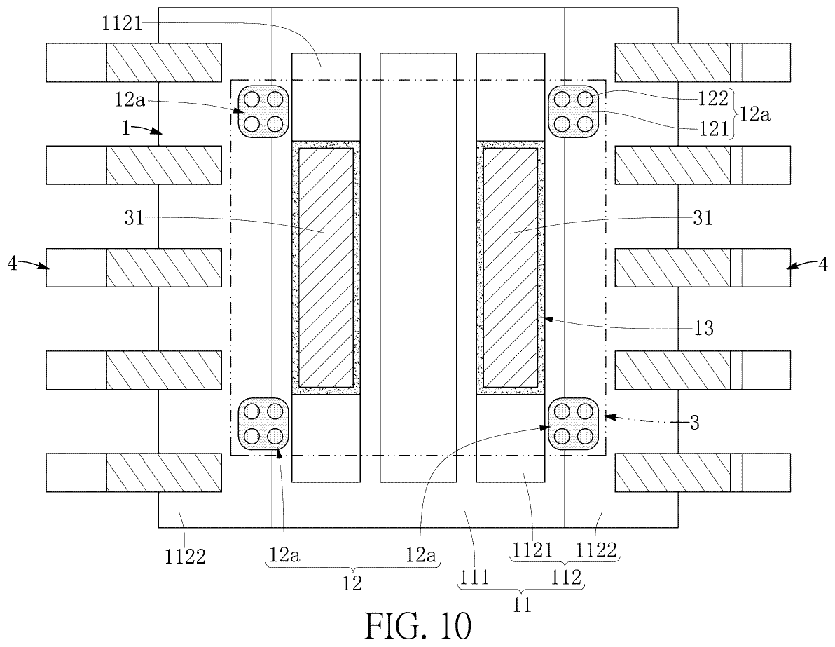

Please refer to FIG. 10, which shows the third embodiment of the present invention. Since this embodiment is similar to the above-mentioned Embodiment I, the common features between the two embodiments will not be described in detail. The differences between this embodiment and the above-mentioned Embodiment I are briefly summarized as follows.

In this embodiment, the size of the first self-correction layer 12 can be reduced according to actual needs. Specifically, the first self-correction layer 12 includes a plurality of correction blocks 12a formed on the first inner metal layer 112, and the plurality of correction blocks 12a are spaced apart from each other and are disposed on the outside of the two first connection pads 1121. The first conductive paste 13 is formed on each of the first connection pads 1121. Each of the correction blocks 12a includes a first glue body 121 and a plurality of first elastic spacers 122 disposed in the first glue body 121. The relevant features of the first glue body 121 and the first elastic body 122 in this embodiment are generally the same as that of the above-mentioned embodiment I, and will not be described again here.

The chip body 33 is disposed on the first self-correction layer 12, and multiple corners of the chip body 33 are respectively disposed on the plurality of correction blocks 12a. Each of the first bonding pads 31 is connected to one of the first conductive pastes 13 so that the power chip 3 is electrically coupled to the first carrier 11. The top edges of the plurality of first elastic spacers 122 (e.g., elastic balls) of each correction block 12a are substantially aligned with the top surface of the first glue body 121 and are in contact with the first surface 331 of the power chip 3, thereby effectively preventing the power chip 3 from being tilted relative to the first carrier 11 so as to achieve better reliability.

In addition, the size of the second self-correction layer 22 can also be reduced according to actual needs, which will not be described in detail here.

### Technical Effects of Embodiments of the Present Invention

To sum up, in the power chip package structure and the manufacturing method thereof disclosed in the embodiments of the present invention, the first self-correction layer is disposed between the first carrier and the power chip, so that during the production process of the power chip package structure, the power chip can be maintained in a preset position by the plurality of first elastic spacers, thereby preventing the power chip from being tilted relative to the first carrier, so as to achieve better reliability performance. . . . In addition, the size of the first self-correction layer can be adjusted according to actual needs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing a power chip package structure, comprising:
a pre-step: providing a first carrier, including a first ceramic board and a first inner metal layer formed on an inner plate surface of the first ceramic board, wherein the first inner metal layer comprises at least one first connection pad;
a forming step: forming a first self-correction layer on the first inner metal layer, which comprises at least one first slot exposing the at least one first connection pad, wherein the first self-correction layer comprises a first glue body in a partially-cured state and a plurality of first elastic spacers disposed in the first glue body;
a filling step: filling at least one first conductive paste into the at least one first slot;
a chip placement step: using a jig to place a power chip on the first self-correction layer and the at least one first conductive paste, so that the at least one first bonding pad of the power chip is connected to the at least one first conductive paste, and at least one of the plurality of first elastic spacers is compressed and deformed by the power chip;
a self-correction step: removing the jig to restore the compressed and deformed at least one of the plurality of first elastic spacers to its original shape, thereby pushing and moving the power chip to a preset position; and
a curing step: sintering the first conductive paste and curing the first glue body to fix the power chip to the at least one first conductive paste and the first self-correction layer.

2. The method according to claim 1, wherein number of the at least one first connection pad, number of the at least one first slot, number of the at least one first bonding pad, and number of the at least one first conductive paste are two for each.

3. The method according to claim 1, wherein in the pre-step, the first inner metal layer is formed with at least one gap surrounding the at least one first connection pad, and in the forming step, the first glue body fills the at least one gap.

4. The method according to claim 1, wherein the first glue body is heated during the chip placement step so that fluidity of the first glue body in the self-correction step is higher than fluidity of the first glue body in the forming step.

5. The method according to claim 1, wherein each of the plurality of first elastic spacers is an elastic ball made of polymer material, and the at least one first conductive paste is a sintering silver paste.

6. The method according to claim 5, wherein top edges of the plurality of elastic balls are substantially aligned with a top surface of the first glue body and are in contact with the power chip.

7. The method according to claim 1, wherein the first carrier is a direct bonded copper (DBC), a direct plated copper (DPC), or an active metal brazing (AMB) ceramic substrate and includes a first outer metal layer, and the first inner metal layer and the first outer metal layer are respectively sintered and fixed to the inner plate surface and an outer plate surface of the first ceramic board.

8. A power chip package structure, comprising:
a first carrier comprising a first ceramic board and a first inner metal layer formed on an inner plate surface of the first ceramic board, wherein the first inner metal layer comprises at least one first connection pad;
a first self-correction layer formed on the first inner metal layer, wherein the first self-correction layer and at least one of the first connection pads jointly form at least one first slot, wherein the first self-correction layer comprises a first glue body and a plurality of first elastic spacers disposed in the first glue body;
at least one first conductive paste filled into the at least one first slot; and
a power chip, comprising:
a chip body disposed on the first self-correction layer; and
at least one first bonding pad formed on a first surface of the chip body, wherein the at least one first bonding pad is connected to the at least one first conductive paste, so that the power chip is electrically coupled to the first carrier.

9. The power chip package structure according to claim 8, wherein each of the first elastic spacers is an elastic ball made of polymer material, and the at least one first conductive paste is a sintering silver paste.

10. The power chip package structure according to claim 9, wherein top edges of the plurality of elastic spacers are substantially aligned with a top surface of the first glue body and are in contact with the first surface of the power chip.

11. The power chip package structure according to claim 8, wherein number of the at least one first connection pad, number of the at least one first slot, number of the at least one first bonding pad, and number of the at least one first conductive paste are two for each, wherein the first inner metal layer comprises a thermal pad located between two said at least one first connection pads, and the first self-correction layer and the thermal pad jointly form a receiving slot; the power chip package structure comprises a thermal conductive paste filled into the receiving slot, and the power chip has a heat dissipation pad located between the two said at least one first bonding pads, and the heat dissipation pad is connected to the thermal conductive paste.

12. The power chip package structure according to claim 8 further comprising:
a second carrier comprising a second ceramic board and a second inner metal layer formed on the inner plate surface of the second ceramic board, wherein the second inner metal layer comprises at least one second connection pad;
a second self-correction layer formed on the second inner metal layer, wherein the second self-correction layer and the at least one second connection pad jointly form at least one second slot, wherein the second self-correction layer comprises a second glue body and a plurality of second elastic spacers disposed in the second glue body; and
at least one second conductive paste filled into the at least one second slot;
wherein the power chip comprises at least one second bonding pad formed on a second surface of the chip body, and the second self-correction layer is disposed on the second surface of the chip body, wherein the at least one second bonding pad is connected to the at least one second conductive paste, so that the power chip is electrically coupled to the second carrier.

13. The power chip package structure according to claim 12, wherein the power chip package structure further comprises a plurality of pins that are spaced apart from each other around the power chip and clamped and fixed between the first carrier and the second carrier, wherein each of the plurality of pins is electrically coupled to the first carrier and the second carrier.

14. The power chip package structure according to claim 12, wherein the first surface of the power chip is completely covered by the first self-correction layer and the at least one first conductive paste, and the second surface of the power chip is completely covered by the second self-correction layer and the at least one second conductive paste.

15. The power chip package structure according to claim 12, wherein the first carrier and the second carrier are each a direct bonded copper (DBC), a direct plated copper (DPC), or an active metal brazing (AMB) ceramic substrate, wherein the first carrier comprises a first outer metal layer, and the second carrier comprises a second outer metal layer, wherein the first inner metal layer and the first outer metal layer are respectively sintered and fixed to the inner plate surface and an outer plate surface of the first ceramic board, and the second inner metal layer and the second outer metal layer are respectively sintered and fixed to the inner plate surface and an outer plate surface of the second ceramic board.

16. A power chip package structure, comprising:
a first carrier comprising a first ceramic board and a first inner metal layer formed on an inner plate surface of the first ceramic board, wherein the first inner metal layer comprises at least one first connection pad;
a first self-correction layer comprising a plurality of correction blocks formed on the first inner metal layer, wherein the plurality of correction blocks are arranged spaced apart from each other and surround outside of the at least one first connection pad, wherein each of the plurality of correction block comprises a first glue body and a plurality of first elastic spacers disposed in the first glue body;
at least one first conductive paste formed on the at least one first connection pad; and
a power chip, comprising:
a chip body disposed on the first self-correction layer, wherein multiple corners of the chip body are respectively disposed on the plurality of the correction blocks; and
at least one first bonding pad formed on a first surface of the chip body, wherein the at least one first bonding pad is connected to the at least one first conductive paste, so that the power chip is electrically coupled to the first carrier.

17. The power chip package structure of claim 16, wherein each of the first elastic spacers is an elastic ball made of polymer material, and the at least one first conductive paste is a sintering silver paste, wherein top edges of the plurality of elastic balls of each of the plurality of correction blocks are substantially aligned with a top surface of the first glue body and are in contact with the first surface of the power chip.

18. The power chip package structure according to claim 17, wherein the top edges of the plurality of elastic balls of each of the plurality of correction blocks are substantially aligned with the top surface of the first glue body and are in contact with the first surface of the power chip.
